(19) United States
(12) Patent Application Publication
(10) Pub. No.: US 2019/0371949 A1
(43) Pub. Date: Dec. 5, 2019

(54) SOLAR CELL AND A METHOD FOR MANUFACTURING A SOLAR CELL

(71) Applicant: SOFTPV INC., Seongnam-si (KR)

(72) Inventors: Hyeon Woo AHN, Daejeon (KR); Sung Gue LEE, Yongin-si (KR); Yong Woo SHIN, Seongnam-si (KR)

(21) Appl. No.: 16/426,266

(22) Filed: May 30, 2019

(30) Foreign Application Priority Data
Jun. 5, 2018 (KR) 10-2018-0064896

(51) Int. Cl. H01L 31/0384; H01L 31/028; H01L 31/0216; H01L 31/0224; H01L 31/054; H01L 31/18

(52) U.S. Cl. CPC H01L 31/03845; H01L 31/028; H01L 31/02168; H01L 31/1892; H01L 31/0543; H01L 31/0547; H01L 31/1804; H01L 31/022425

(57) ABSTRACT

A method of manufacturing a solar cell is disclosed. The method comprises the steps of: (a) positioning a plurality of silicon particles comprising a first layer on the outside on the dummy substrate including a plurality of holes corresponding to the holes; (b) forming an optically transparent layer on the dummy substrate to include at least one of the silicon particles; (c) removing the dummy substrate and exposing a portion of the first layer; (d) forming a plurality of first electrodes, wherein the first electrode is connected to the exposed first layer of each of the silicon particles; (e) forming an insulating layer on the first electrode; (f) removing a part of the first layer of silicon particle; (g) forming a second electrode electrically connected to the portion where the first layer of the silicon particle is removed.

### CROSS-REFERENCE TO RELATED APPLICATIONS

This patent application claims priority under 35 U.S.C. § 119 to Korean Patent Application No. 10-2018-0064896, filed on Jun. 5, 2018, in the Korean Intellectual Property Office, the disclosure of which is incorporated by reference herein in its entirety.

### TECHNICAL FIELD

The present invention relates to a solar cell and a method for manufacturing a solar cell.

### DISCUSSION OF RELATED ART

In a conventional panel-type solar cell, a solar cell using a silicon ball is being developed. However, the optical structure and the wiring structure have not been optimized yet. In addition, various manufacturing methods have been developed to produce a complicated structure, but research on methods for obtaining power productivity and cost competitiveness of other solar cell panels is further needed.

### SUMMARY

The present invention has been made in order to solve the above-mentioned problems, and it is an object of the present invention to provide a solar cell that can reduce manufacturing cost and ensure stability and a method for manufacturing the solar cell.

In order to solve the above problems, a method of manufacturing a solar cell according to an embodiment of the present invention may comprise: the steps of: (a) positioning a plurality of silicon particles comprising a first layer on the outside on the dummy substrate including a plurality of holes corresponding to the holes; (b) forming an optically transparent layer on the dummy substrate to include at least one of the silicon particles; (c) removing the dummy substrate and exposing a portion of the first layer; (d) forming a plurality of first electrodes, wherein the first electrode is connected to the exposed first layer of each of the silicon particles; (e) forming an insulating layer on the first electrode; (f) removing a part of the first layer of silicon particle; (g) forming a second electrode electrically connected to the portion where the first layer of the silicon particle is removed.

In an embodiment, the silicon particle may comprise P-type or N-type silicon, and the first layer comprises a diffusion layer forming a P-N junction on the surface of the light-receiving area of the silicon ball.

In an embodiment, after the step of (a), the method may further comprise the step of: forming a second layer for anti-reflection on the silicon particles placed on the dummy substrate.

In an embodiment, the method may further comprise the step of: forming a second layer for anti-reflection to surround the first layer of the silicon particle before the step of (a), and wherein after removing the dummy substrate, a part of the second layer formed on each of the silicon particles is removed to expose a part of the first layer in the step of (c).

In an embodiment, after the step of (c), the method may further comprise the step of: forming a reflective layer in a region where the dummy substrate is removed.

In an embodiment, the first electrode may comprise a first layer contact portion electrically connected to the first layer of the silicon particle, a connection terminal portion connected to the second electrode, and an extension part for electrically connecting the first layer contact portion and the connection terminal portion, and the second electrode comprises a core contact portion 610 electrically connected to the portion where the first layer of the silicon particle is removed, a connection terminal portion connected to the first electrode, and an extension portion electrically connecting the core contact portion and the connection terminal portion.

In an embodiment, after the step of (g), the method may further comprise the step of: (h) forming a protective layer on the second electrode.

In an embodiment, in the step of (h), the protective layer may comprise an optically transparent layer.

In an embodiment, in the step of (a), the silicon particles may be captured by a template comprising a plurality of inlets and are seated in a plurality of holes on the dummy substrate.

In an embodiment, the silicon particles may be seated in the plurality of holes using a circulation path continuously providing a plurality of silicon particles along the gravity direction.

A method of manufacturing a solar cell according to another embodiment of the present invention may comprise the steps of: (a) positioning a plurality of silicon particles comprising a first layer on the outside on the dummy substrate including a plurality of holes corresponding to the holes; (b) forming an optically transparent layer on the dummy substrate to include at least one of the silicon particles; (c) removing the dummy substrate and exposing a portion of the first layer; (d) forming a plurality of first electrodes, wherein the first electrode is connected to the exposed first layer of each of the silicon particles; (e) removing a part of the first layer of silicon particle; (f) forming an insulating layer on the first electrode; (g) forming a second electrode electrically connected to the portion where the first layer of the silicon particle is removed.

A method of manufacturing a solar cell according to another embodiment of the present invention may comprise the steps of: (a) positioning a plurality of silicon particles comprising a first layer on the outside on the dummy substrate including a plurality of holes corresponding to the holes; (b) forming an optically transparent layer on the dummy substrate to include at least one of the silicon particles; (c) removing the dummy substrate and exposing a portion of the first layer; (d) forming a plurality of first electrodes, wherein the first electrode is connected to the exposed first layer of each of the silicon particles; (e) removing a part of the first layer of silicon particle; (f) forming an insulating layer on the first electrode partially; (g) forming a second electrode electrically connected to the portion where the first layer of the silicon particle is removed.

A solar cell according to another embodiment of the present invention may comprise a plurality of silicon particles comprising a first layer on the outside; an optically transparent layer in which a part of the plurality of silicon particles 100 is embedded; a plurality of upper electrodes formed under the optically transparent layer and electrically connected to the first layer of the silicon particle; a plurality of lower electrodes formed below the corresponding upper electrode and electrically connected to the exposed part of the silicon particle 100 through the portion where the first layer is not formed; an insulating layer placed between the upper electrode and the lower electrode to insulate the upper electrode and the lower electrode.

In an embodiment, the solar cell may further comprise a protective layer disposed under the lower electrode.

In an embodiment, the insulating layer may comprise a plurality of insulating elements corresponding to each of the upper electrode and the lower electrode.

In an embodiment, the first electrode may comprise a first layer contact portion electrically connected to the first layer of the silicon particle, a connection terminal portion connected to the second electrode, and an extension part for electrically connecting the first layer contact portion and the connection terminal portion, and the second electrode comprises a core contact portion electrically connected to the portion where the first layer of the silicon particle is removed, a connection terminal portion connected to the first electrode, and an extension portion electrically connecting the core contact portion and the connection terminal portion.

In an embodiment, the insulating layer may comprise a plurality of insulating elements corresponding to each of the upper electrode and the lower electrode, and the insulating elements are formed to be larger than the first layer contact portion of the corresponding first electrode.

In an embodiment, the insulating layer may comprise a plurality of insulating elements corresponding to each of the upper electrode and the lower electrode, and the insulating elements are formed to be larger than a core contact portion of the corresponding second electrode, and electrically isolate the first contact portion of the corresponding first electrode from the core contact portion and the extended portion of the second electrode.

According to the present invention as described above, a complicated manufacturing process can be simplified, and the production cost of a solar cell using a silicon ball can be improved.

In addition, it is possible to improve the structural stability of a solar cell than a solar cell manufactured according to a conventional manufacturing method.

In addition, it is possible to fabricate a solar cell with much improved transparency than the solar cell manufactured according to the conventional manufacturing method.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a flowchart showing a method of manufacturing a solar cell according to an embodiment of the present invention.

FIGS. 2A and 2B are cross-sectional views of silicon particles used in a method of manufacturing a solar cell according to an embodiment of the present invention.

FIGS. 3A, 3B, 3C, 3D, 3E, 3F, 3G, 3H, 3I, 3J, and 3K are cross-sectional views illustrating a method of manufacturing silicon particles according to an embodiment of the present invention.

FIGS. 4A, 4B, 4C, 4D, and 4E are cross-sectional views illustrating a method of manufacturing silicon particles according to the embodiment of FIG. 2B.

FIG. 5 is a perspective view of a solar cell according to an embodiment of the present invention.

FIG. 6 is a cross-sectional view of a solar cell according to another embodiment of the present invention.

FIGS. 7A and 7B are bottom views of a solar cell according to another embodiment of the present invention.

FIGS. 8A and 8B are views showing a dummy substrate according to an embodiment of the present invention and silicon particles mounted on the dummy substrate.

FIG. 9 is a cross-sectional view of a solar cell according to another embodiment of the present invention.

FIG. 10 is a cross-sectional view of a solar cell according to another embodiment of the present invention.

### DETAILED DESCRIPTION OF EXEMPLARY EMBODIMENTS

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover ail modifications, equivalents and alternatives falling within the spirit and scope of the present invention as defined by the appended requests. Note, the headings are for organizational purposes only and are not meant to be used to limit or interpret the description or claims. Furthermore, note that the word “may” is used throughout this application in a permissive sense (i.e., having the potential to, being able to), not a mandatory sense (i.e., must). The term “include”, and derivations thereof, mean “including, hut not limited to”. The term “coupled” means “directly or indirectly connected”.

The singular expressions include plural expressions unless the context clearly dictates otherwise.

It will be apparent to those skilled in the art that the present invention may be embodied in other specific forms without departing from the essential characteristics thereof.

Hereinafter, embodiments of the present invention will be described in detail with reference to the drawings. In the figs, same reference numerals refer to same elements.

A Manufacturing Method of a Solar Cell

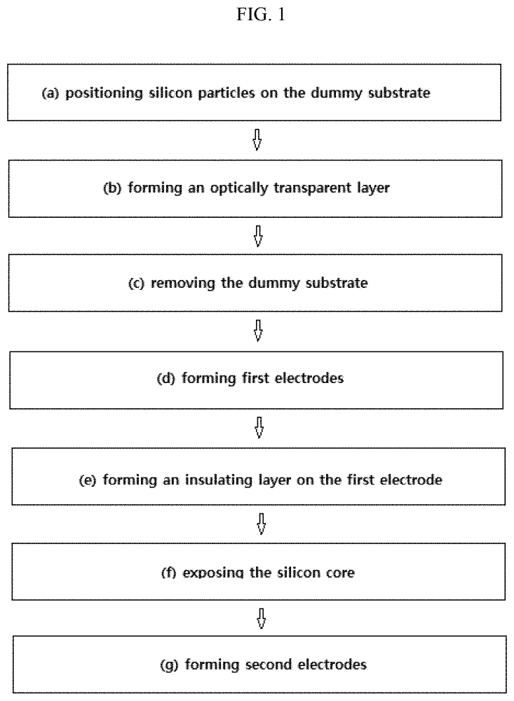

FIG. 1 is a flowchart showing a method of manufacturing a solar cell according to an embodiment of the present invention.

A method of manufacturing a solar cell according to an embodiment of the present invention includes the steps of: (a) placing a plurality of silicon particles corresponding to the plurality of holes comprised in a dummy substrate, (b) forming an optically transparent layer on the dummy substrate to include at least some of the silicon particles, (C) removing the dummy substrate and exposing a portion of the first layer, (d) forming a plurality of first electrode connected the exposed first layer of each silicon particle, (e) forming an insulating layer on the first electrode, (f) removing a portion of the first layer of the silicon particles, and (g) forming a second electrode electrically connected to the region where the first layer of the silicon particle is removed.

The silicon particle (100) used in this embodiment can be separately manufactured before the manufacturing process of the present solar cell. The silicon particle (100) includes a silicon core (110) and a first layer (120). The silicon particle 100 may further include additional components in addition to the essentially included components, such as the silicon core 110 and the first layer 120. If a silicon particle comprises additional components, additional processes associated therewith may be added. However, the order of the basic processes may include the presented steps sequentially.

The second layer 130 for antireflection may be formed in various ways. The second layer 130 may be formed in the process of forming the silicon particle 100. In this case, the second layer 130 is entirely coated on the outer surface of the first layer 120.

In addition, the second layer 130 for antireflection can be formed through a separate coating process after the silicon particle 100 is placed on the dummy substrate.

Depending on how the second layer 130 is formed, (c) the process of exposing a portion of the first layer may be varied.

In addition, various processes may be added and modified, including core processes.

Hereinafter, specific processes will be described with reference to the drawings.

Silicon Particles

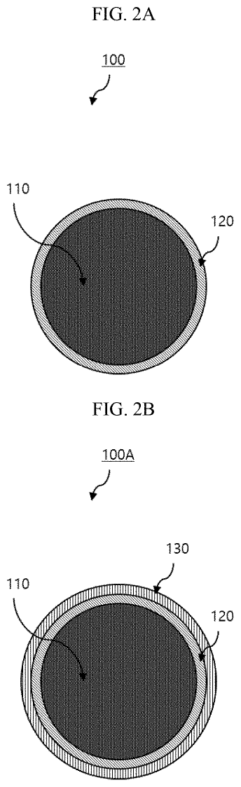

FIG. 2A is a cross-sectional view of a silicon particle used in a method for manufacturing a solar cell according to an embodiment of the present invention.

Referring to FIG. 2A, a silicon particle 100 according to an embodiment of the present invention basically includes a silicon core 110 and a first layer 120. The silicon particle 100 may be manufactured in a ball shape or a polyhedral shape. The polyhedral shape includes a cubic structure.

The silicon particle 100 includes P-type or N-type silicon, and a first layer 120, which is a diffusion layer forming a P-N junction, is formed outside the silicon particle 100. Silicon particle 100 may further include a P-type or N-type dopant.

Here, the first layer receives energy by the sunlight, and the excited electrons move accordingly. This creates a current.

In the drawing, the silicon particle 100 is formed of P-type silicon, and the first layer 120, which is an N-type diffusion layer, is formed on the surface of the silicon particle 100.

The silicon particle 100 may be manufactured by performing a doping process.

POCl3, H3PO4, and the like containing a Group 5 element are diffused at a high temperature to the silicon core 110 of the p-type silicon. The first layer 120, which is an N-type diffusion layer, can thereby be formed. In addition, the silicon core 110 may have a structure formed of silicon itself, or may have a structure in which an insulating ball is coated with silicon. The insulating balls may be made of various materials such as glass and ceramics.

FIG. 2B is a cross-sectional view of a silicon particle according to another embodiment of the present invention. Referring to FIG. 2B, the silicon particle 100A comprises a silicon core 110, a first layer 120, and a second layer 130. The second layer 130 is a coating layer coated with an antireflective material outside the first layer 120. When the second layer 130 is previously formed in this way, there may be a change in the manufacturing process. Here, the silicon particle 100A is formed in a ball shape.

And the silicon particle may be formed to comprise a texture shape so as to reduce the reflectance of the silicon core 110. A texture shape is formed on the surface of the first layer.

In addition, the configurations of the P-type and N-type semiconductors of the silicon core 110 and the first layer 120 may be reversed. Accordingly, the silicon core 110 may be formed in an N-type, and the first layer 120 may be formed in a P-type semiconductor.

Arrangement of Silicon Particles (Step a)

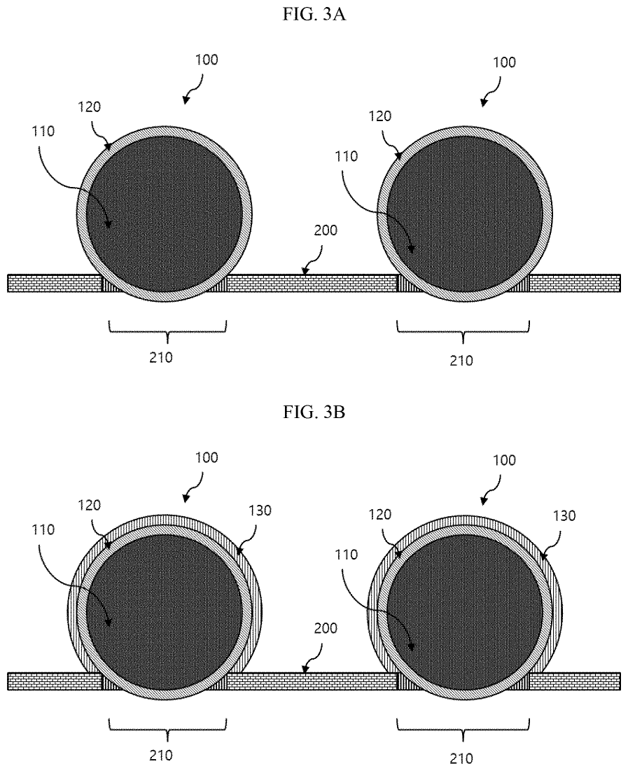

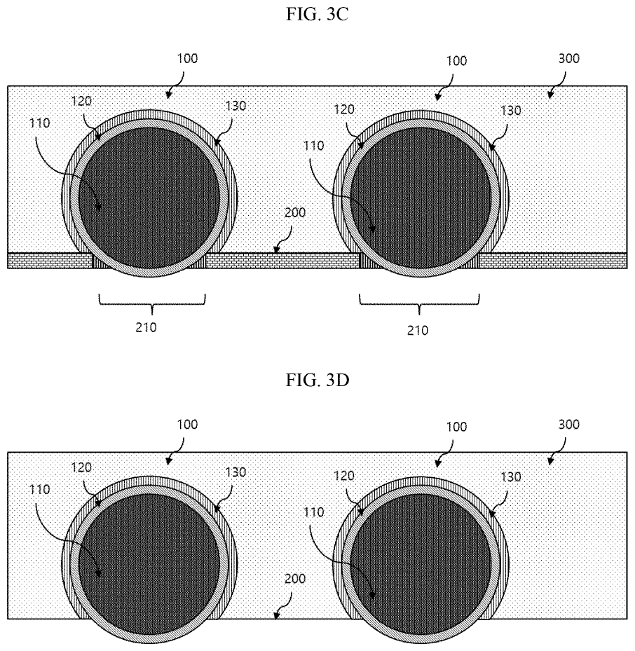

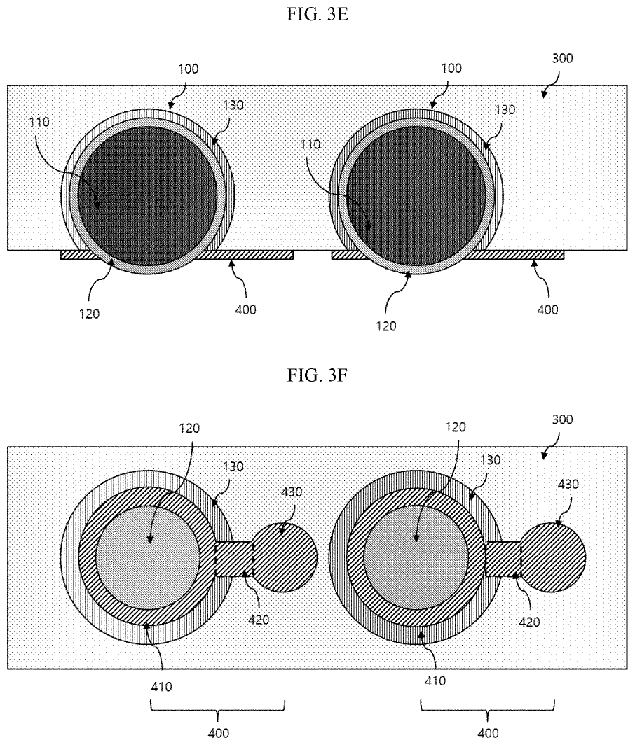

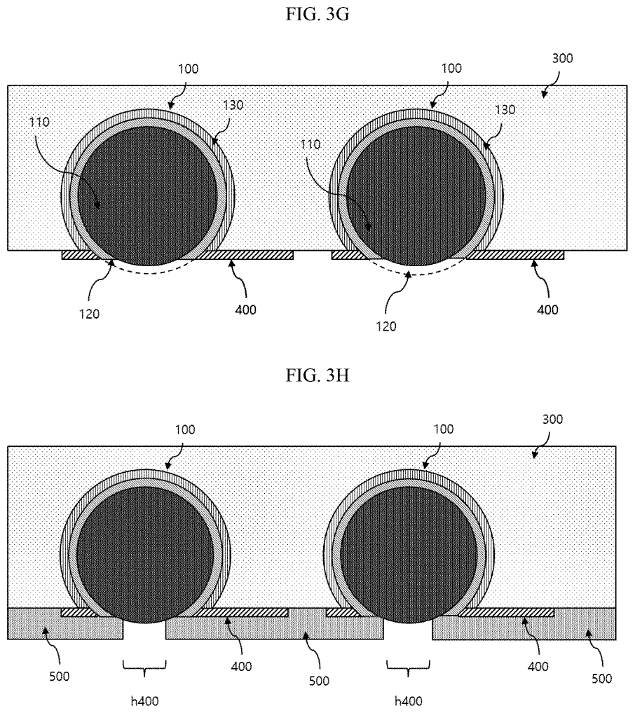

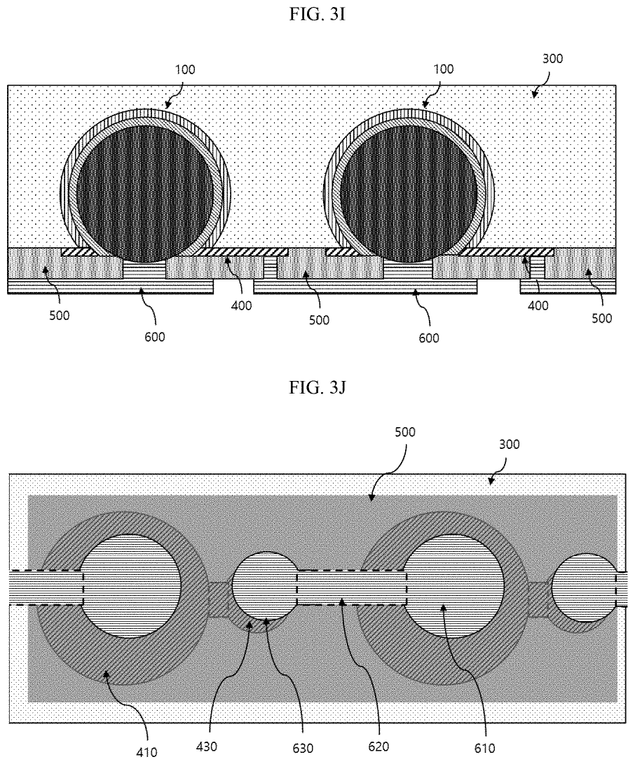

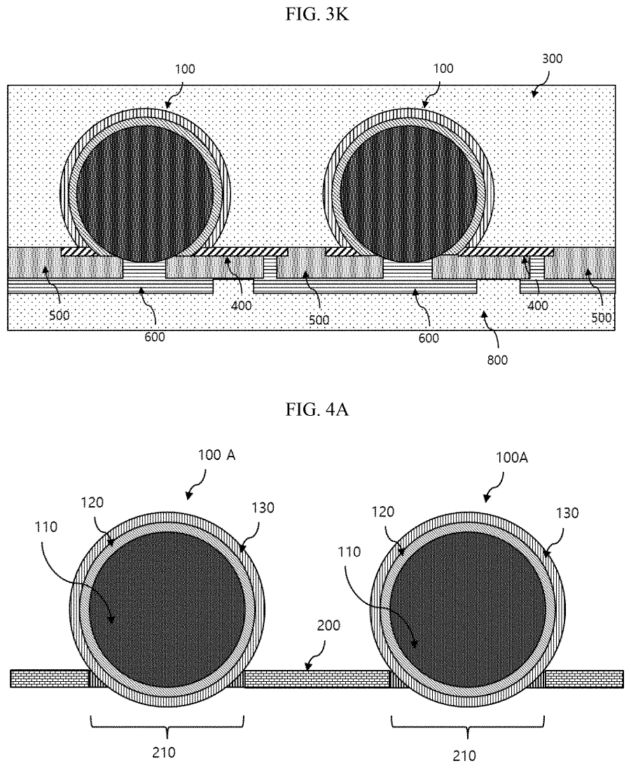

FIG. 3A is a cross-sectional view of a silicon particle and a dummy substrate on which the silicon particle is disposed according to an embodiment of the present invention.

Referring to FIG. 3A, silicon particles 100 are disposed in the holes 210 of the dummy substrate 200, respectively. In this step, the dummy substrate 200 is used for disposing the respective silicon particles 100. The dummy substrate 200 will be removed later. Therefore, it is not responsible for the functional part of the actual solar cell.

The dummy substrate 200 may be formed of a material and a thickness that can be easily removed. The size of the hole 210 of the dummy substrate 200 is determined based on the degree to which the silicon particle 100 is to be exposed. How much the silicon particle 100 is to be exposed compared to the upper surface of the dummy substrate 200 is determined according to the size of the hole 210.

Also, the spacing of the holes 210 determines the spacing of the silicon particles 100. Therefore, various shapes of the dummy substrate 200 can be used depending on the desired density and configuration. The arrangement of the silicon balls 100 can be variously configured by adjusting the arrangement of the holes 210.

The hole 210 of the dummy substrate 200 can be formed by photolithography. The dummy substrate 200 is composed of a dry film resist (DFR, Dry Film Resist or Dry Film photo Resist). The dry film resist may be typically formed of a film containing acrylic.

In this step, as a method of providing the silicon particles 100 on the dummy substrate 200, various methods can be applied. As an example, vacuum suction may be used. For example, the silicon particles 100 are captured by vacuum suction. The captured silicon particles 100 can be provided on the dummy substrate 200 at the positions of the holes.

In this case, a template including a plurality of suction ports can be used. A vacuum is inhaled from the opposite side of the template to seat a plurality of silicon particles (100) on the suction ports. The template is moved onto the dummy substrate 200, and the vacuum is removed to release the silicon particles 100. The silicon particles 100 can be seated at the positions of the holes 210 of the dummy substrate 200.

As another method, a circulation cycle can be used. A plurality of silicon particles 200 are provided continuously from the upper part of the inclined dummy substrate 200. And the silicon particles 100 that are not seated in the holes are collected from the bottom. The collected silicon particles 100 are again provided at the top. The silicon particles 100 may be disposed on the dummy substrate 200 by forming this circulation structure.

Formation of an Antireflection Film (Before Step b)

FIG. 3B is a cross-sectional view of a solar cell in a process of forming an antireflection film in a method of manufacturing a solar cell according to an embodiment of the present invention.

Referring to FIG. 3B, the second layer 130, which is an anti-reflection layer, is coated on the silicon particles 100 disposed on the dummy substrate 200. As described above, the second layer 130 may be coated in the process of forming the silicon particles 100.

According to the present embodiment, the silicon ball 100 initially does not have a second layer 130 and is then coated with a second layer 130 on the silicon ball 100 on the substrate 200.

As the antireflection film, tin oxide, titanium dioxide, zinc oxide, aluminum oxide, aluminum nitride, silicon dioxide, silicon nitride, etc. can be used.

Other methods will be described in another embodiment to be described later.

Formation of an Optically Transparent Layer and Removal of the Dummy Substrate (Steps b and c)

FIG. 3C is a cross-sectional view of a solar cell in the process of forming an optical transparent layer in a method of manufacturing a solar cell according to an embodiment of the present invention. FIG. 3D is a cross-sectional view of the solar cell with the dummy substrate removed.

Referring to FIGS. 3C and 3D, the optically transparent layer 300 is formed on the dummy substrate 200 to cover a portion of the silicon particles 100. Thereafter, the dummy substrate 200 is removed and a part of the silicon particle 100 is exposed under the optical transparent layer 300.

As the optically transparent layer 300, OCM (Optically Clear Material) having high transparency, low strain and low stress can be used. The OCM may be formed of glass. Since the sunlight must be transmitted and delivered to the silicon ball 100 of the solar cell, the OCM should be a material having high transparency. Also, deformation such as shrinkage due to external heat should be minimized. A material having elasticity can be used. The OCM can be chosen so that the solar cell to be completed later will have overall flexibility elasticity, deformability and resilience.

The optically transparent layer 300 may be formed by applying a resin or the like used for the optically transparent layer on the dummy substrate 200 and hardening the same. When the dummy substrate 200 is removed after the optically transparent layer 300 is formed, a part of the silicon particle 100 is exposed to the outside of the optically transparent layer 300, and then an electrode or the like electrically connected to the silicon particle 100 can be easily formed.

The optical transparent layer (OCM) is formed by applying a liquid phase layer and solidifying it. As the OCM, PET (polyethylene terephthalate) comprising UV stabilizer, PC (polycarbonate) and the like may be used.

Formation of the First Electrode (Step e)

FIG. 3E is a cross-sectional view of the solar cell in the process of forming the first electrode. FIG. 3F is a bottom view of the solar cell of FIG. 3E in which the first electrode is formed.

Referring to FIG. 3E, a first electrode 400, which is electrically connected to the first layer 120, is formed around the exposed first layer 120. In general, the first electrode 400 may be formed as a layer covering the exposed first layer 120 and then etched except for a desired shape.

FIG. 3F is a bottom view of the solar cell in which the first electrode of FIG. 3E is formed. The first electrode 400 includes a first layer contact portion 410 electrically connected to the first layer 120 of the silicon particle 100, a connection terminal portion 430 connected to the second electrode, and an extension part 420 electrically connecting a first layer contact portion 410 with the connection terminal part 430.

In the drawing, it appears that the first layer contact portion 410 is formed to be slightly smaller than the shape of the entire silicon particle 100. When actually fabricated, the size of the first layer contact portion 410 can be reduced. As a result, the circuit pattern except for the silicon particle 100 can be formed in a fine structure so that the circuit pattern cannot be seen by the naked eye as a whole.

The first electrode and the second electrode to be described later may be formed of various materials. For example, the material comprises copper, silver or aluminum, etc.

Removal of the First Layer and Formation of the Second Electrode (Steps f and g)

FIGS. 3G to 3K are views showing a process of removing the first layer and forming a second electrode.

FIG. 3G is a cross-sectional view of a solar cell in a process in which a part of the first layer and a part of the first electrode are removed in a method of manufacturing a solar cell according to an embodiment of the present invention. FIG. 3H is a cross-sectional view of the solar cell in a process in which a part of the first layer and a part of the first electrode are removed and an insulating layer is formed. FIG. 3I is a cross-sectional view of a solar cell having a second electrode formed. FIG. 3J is a bottom view of FIG. 3I.

Referring to FIG. 3G first, in the silicon particle 100 exposed to the outside of the optically transparent layer 300, overlapped portion of the first layer 120 and the first electrode 400 is removed to expose the silicon core 110.

The first layer 120 and the first electrode 400 should be directly connected to each other and the silicon core 110 and the second electrode 600 should be directly connected to each other. Since the first electrode is formed outside the first layer 120, the first electrode 400 is not in electrical contact with the silicon core 110. In order to prevent the second electrode 600 from contacting the first electrode 400 or the first layer 120, a separate insulating layer is formed.

Referring to FIG. 3H, insulating layers 500 are formed on a layer on which the first electrodes 400 are formed. The insulating layer 500 has an effect of preventing the first electrode 400 and the second electrode 600 from being electrically connected to each other where the first electrode 400 and the second electrode 600 need not be electrically connected. Basically, the insulating layers 500 are formed to cover all of the first electrodes 400 and are formed to expose the silicon core 110 for the second electrode.

Referring to FIG. 3I, second electrodes 600 are formed on the insulating layers 500 formed in FIG. 3H. The second electrode is electrically connected to the exposed silicon core 110 of the silicon particle 100 and is electrically connected to the first electrode connected to the first layer 120 of the adjacent silicon particle 100. Thus, a circuit in which each silicon particle 100 is connected in series with one another is formed.

Referring to FIG. 3J, the structure in which the first electrode 400 and the second electrode 600 are connected can be shown. Like the first electrode, the second electrode 600 includes a core contact portion 610 electrically connected to the silicon core 110 of the silicon particle, a connection terminal portion 630 connected to the first electrode, and an extension part 620 electrically connecting the core contact portion 610 and the connection terminal part 630. The connection terminal portion 430 of the first electrode and the connection terminal portion 630 of the second electrode are electrically connected through the through hole 700.

The through hole 700 may be integrally formed with the core contact portion 610, the extension portion 620, and the connection terminal portion 630 of the second electrode during the formation of the second electrode.

Formation of a Protective Layer (Additional Step)

FIG. 3J is a cross-sectional view of the solar cell after the protective layer 800 is formed on the second electrode 600. The protective layer 800 should be formed to prevent the second electrode 600 from being exposed to the outside. The protective layer 800 may be formed of a general insulating layer, and an OCM layer of the same material as the optically transparent layer 300 can be formed.

In this embodiment, since the shape of the silicon particle 100 of the solar cell is spherical, electric power can be produced by solar light supplied from the lower part as well as the upper part. Therefore, the protective layer for protecting the lower portion can be manufactured so that transparency can be ensured and light can be introduced.

As mentioned above, the material of the protective layer may be the same as the material of the OCM. Therefore, PET (polyethylene terephthalate) comprising UV stabilizer, PC (polycarbonate), or the like may be used.

Formation of Reflective Layer

Although not shown in the drawing, in another embodiment of the present invention, after step (c) in which the dummy substrate 200 is removed, a reflective layer can be formed. Here, the reflective layer may be formed as a mirror solar resist (MSR) layer. Depending on the type of solar cell, there is a case where the light from the lower part is not delivered into the inside and the light supplied from the upper part needs to be reflected. In this case, a reflective layer can be formed inside of the solar cell.

If necessary, this reflective layer may be separately formed under the lowermost protective layer 800.

Process of Using Embodiments of Silicon Ball Comprising a Second Layer

FIG. 2B is a cross-sectional view of a silicon particle according to another embodiment of the present invention. Referring to FIG. 2B, the silicon particle 100A includes a silicon core 110, a first layer 120, and a second layer 130. The second layer 130 can be formed in advance when the silicon particle 100A is manufactured.

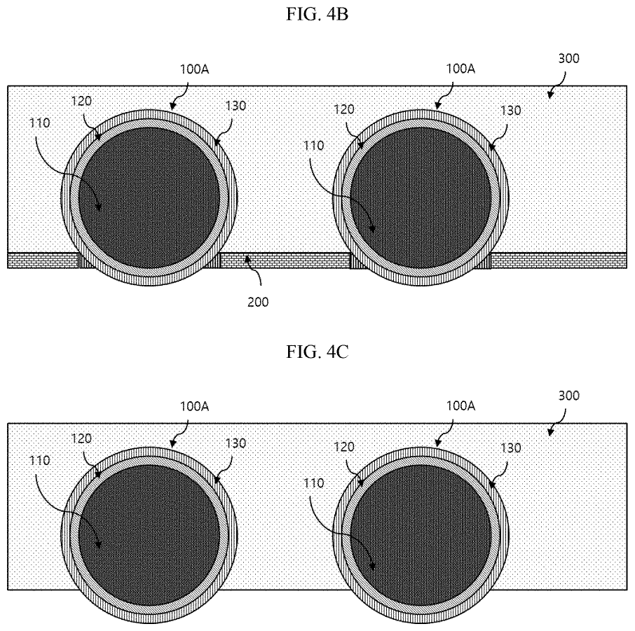

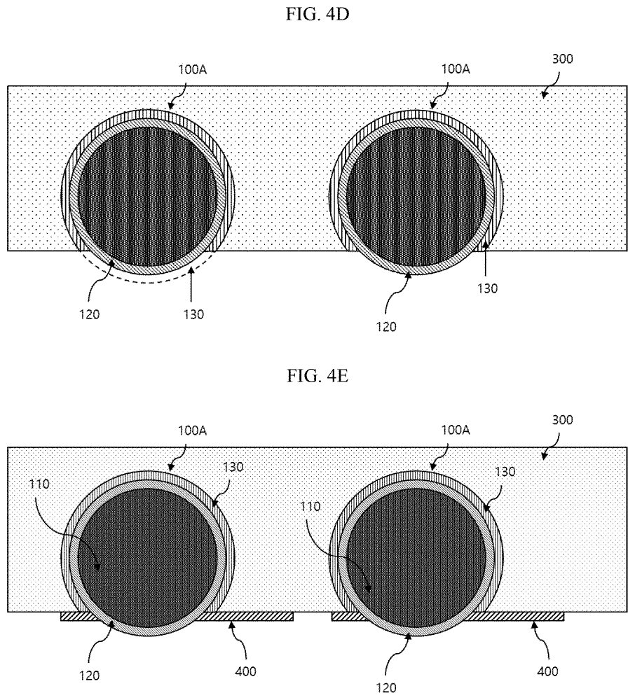

FIG. 4A to 4E are cross-sectional views related to a manufacturing process of a solar cell to which the embodiment according to FIG. 2B is applied.

Compared with the fabrication process of the embodiment according to FIGS. 3A to 3K, the processes of FIGS. 3A to 3D are compared with those of FIGS. 4A to 4D.

The cross-sectional view of FIG. 3E process and the cross-sectional view of FIG. 4E process are substantially the same, and the process steps after FIG. 4E are substantially the same as the processes of FIGS. 3E to 3J.

Hereinafter, duplicate description will be omitted, and differences in the process will be mainly described.

Referring to FIGS. 4A and 4C, a silicon particle 100A including a second layer 130 is disposed in the hole 210 of the dummy substrate 200. At this time, since the size of the silicon particle 100A is increased by the thickness of the second layer 130, the size and the interval of the holes 210 should be adjusted accordingly. The optically transparent layer 300 is formed on the dummy substrate 200 on which the silicon particles 100A are disposed. After the optically transparent layer 300 is formed, the dummy substrate 200 is removed.

The manufacturing steps of FIG. 4c correspond to the manufacturing steps of FIG. 3d. In this embodiment, the second layer 130 is already formed. Referring to FIG. 4C, the second layer 130 of the silicon particle 100A exposed outside of the optically transparent layer 300 is exposed.

Referring to FIG. 4D, the second layer 130 exposed outside of the optically transparent layer 300 is removed. The first layer 120 should be exposed to form a first electrode that is electrically connected to the first layer 120. A first electrode is formed over the exposed first layer (120).

FIGS. 4E and 3E are steps for forming the first electrode. Referring to FIG. 4E, the process is substantially the same as that of FIG. 3E. After the step for forming the first electrode, the steps of forming the insulating layer and forming the second electrode proceed substantially the same.

Formed Solar Cell

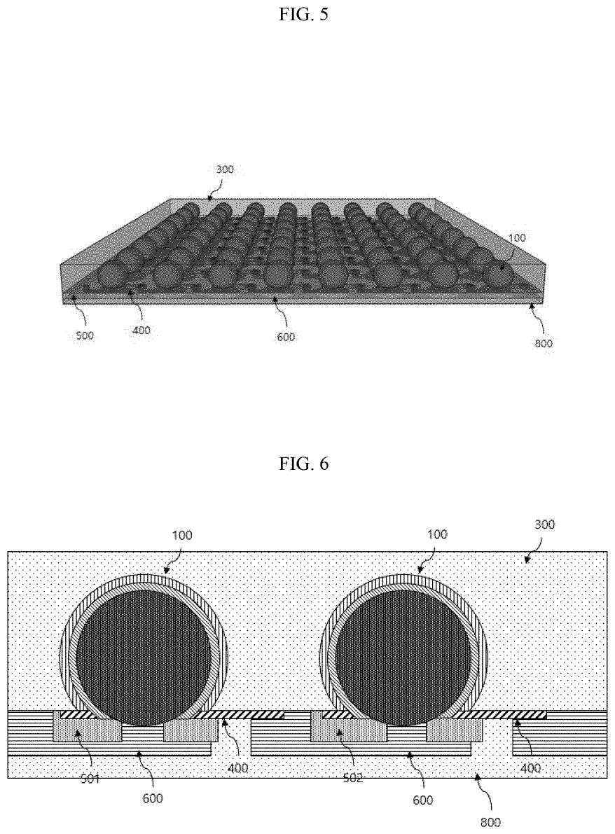

FIG. 5 is a schematic perspective view illustrating a solar cell manufactured according to an embodiment of the present invention.

Referring to FIG. 5, a solar cell manufactured according to the manufacturing method of this embodiment can be shown. The solar cell of the present embodiment has the insulating layer 500 and the protective layer 800 formed under the optically transparent layer 300 in which the plurality of silicon particles 100 are embedded. And the first electrode 400 and the second electrode 600 are formed beneath the silicon particles 100 so that each of the plurality of silicon particles 100 is effectively connected in series.

In the Fig, the distances between the respective silicon particles 100 are very close to each other and the silicon particles 100 are largely expressed. However, compared to the actual diameter of the silicon particles 100, the distance between each silicon particle 100 is designed to be very far. Each layer 300, 500, 800 is optically transparent, and it is made to be perceived as a slightly colored glass panel. Here, because the second layer 130 of the silicon particle 100 is formed so as to prevent reflection, the color of the slightly colored glass panel can be blue overall.

If desired, by controlling the compositions of the second layer or the optically transparent layer 300, a transparent layer of a desired color can be produced. And by controlling the density of the silicon particles 100 for a respective solar cell, optimized settings for power output and transparency can be achieved.

Solar Cell Structure to Improve Transparency

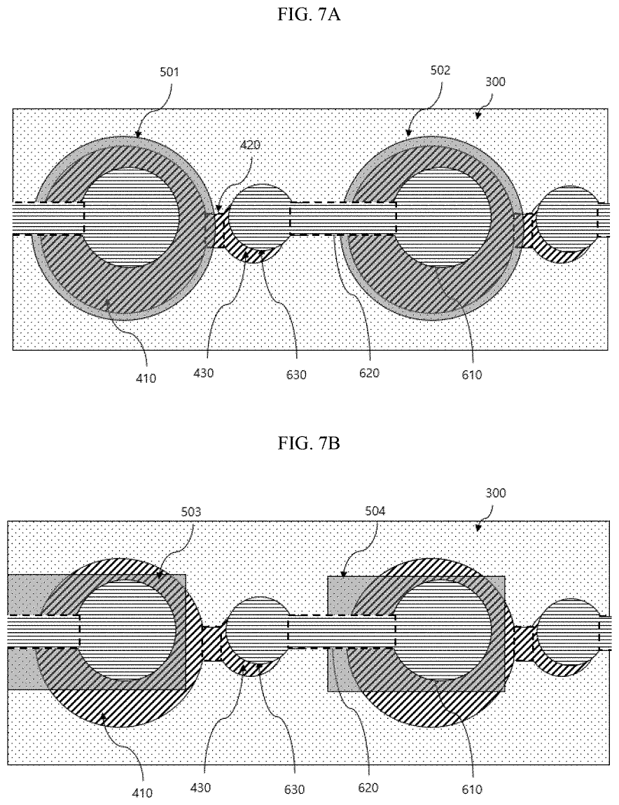

FIG. 6 is a cross-sectional view of a solar cell according to another embodiment of the present invention. FIGS. 7A and 7B are bottom views of a solar cell according to another embodiment of the present invention.

Referring to FIG. 6, the solar cell according to the present embodiment comprises a plurality of silicon particles 100, an optically transparent layer 300, a plurality of upper electrodes 400, a plurality of lower electrodes 600, and an insulating layer. Each of the plurality of silicon particles 100 comprises a first layer on the outside.

A part of the each of the plurality of silicon particles 100 is embedded in the optically transparent layer 300.

The plurality of upper electrodes 400 are formed under the optically transparent layers 300 and the upper electrode is electrically connected to the first layer 120 of the silicon particle 100.

Each of the lower electrodes 600 is formed below the corresponding upper electrode 400 and is electrically connected to the exposed part of the silicon particle 100 through the portion where the first layer is not formed.

The insulating layers are between the upper electrode and the lower electrode to insulating the upper electrode and the lower electrode.

In addition, a protective layer 800 may be further formed under the lower electrode 600.

Further, the upper electrode, the lower electrode, and the insulating layer may be formed only on a part of the plane of the optically transparent layer. The upper and lower electrodes of the at least one silicon particle may be formed independently from the upper electrode and lower electrodes of each of the adjacent silicon particles.

In this embodiment, the insulating layer is not formed as one layer as a whole, but only insulating elements 501 and 502 can be partially disposed so as to isolate the first electrode 400 and the second electrode 600 from each other. Therefore, the portion formed of the non-transparent element in the solar cell becomes smaller, and the transmittance of the entire solar cell can be improved.

Referring to FIG. 7A first, the first electrode comprises a first layer contact portion 410 electrically connected to the first layer of the silicon ball, a connection terminal portion 430 connected to the second electrode, and an extension part 420 for electrically connecting the first layer contact portion 410 and the connection terminal portion.

The second electrode comprises a core contact portion 610 electrically connected to the portion where the first layer of the silicon ball is removed, a connection terminal portion 630 connected to the first electrode, and an extension portion 620 electrically connecting the core contact portion 610 and the connection terminal portion 630.

The insulating elements 501 and 502 are formed to be larger than the first layer contact portion 410 of the first electrode. The first layer contact portion 410 of the first electrode and the core contact portion 610 and the extension portion 620 of the second electrode can be insulated. The insulating elements 501 and 502 are formed to be as small as possible to improve the transmittance of the solar cell.

Referring to FIG. 7B, the insulating elements 503 and 504 are formed to be larger than the core contact portion 610 of the corresponding second electrode. And the insulating elements 503 and 504 can insulate the first contact portion 410 of the corresponding first electrode and the core contact portion 610 and the extension portion 620 of the second electrode.

Therefore, by a method different from the embodiment of FIG. 7A, it is possible to improve the transmittance of the entire solar cell by securing a minimum insulation area.

The Size And Shape of the Product According to the Embodiment

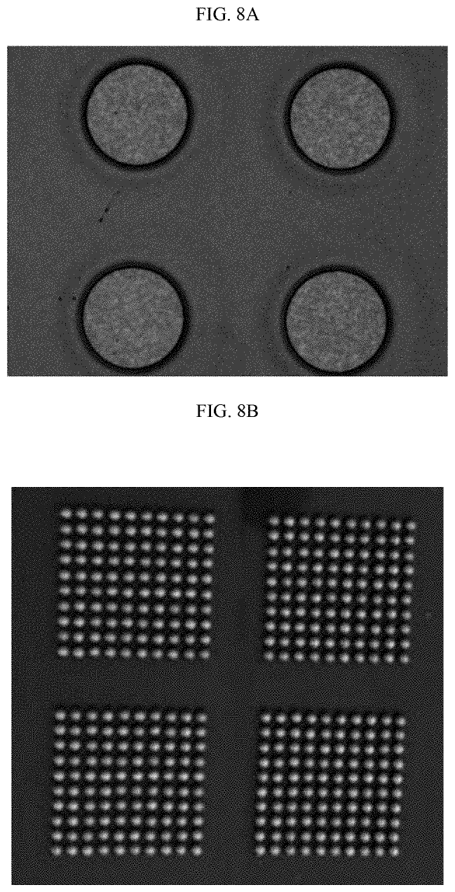

FIGS. 8A and 8B are views showing a dummy substrate according to an embodiment of the present invention and silicon particles mounted on the dummy substrate.

The diameter of the hole on the dummy substrate on which the silicon particles are to be deposited was formed to be approximately 600 um. In this case, the diameter of the silicon particle to be settled is about 1.1 mm.

Of course, the diameter of the hole may have different diameters depending on the size of the silicon particles and the extent to which the silicon particles are exposed.

Referring to FIG. 8B, the particles set as described above are set having uniform intervals as shown in FIG. 8B. Settlement of the particles can be applied in various arrangement methods.

Silicon Particles of Cubic Shape

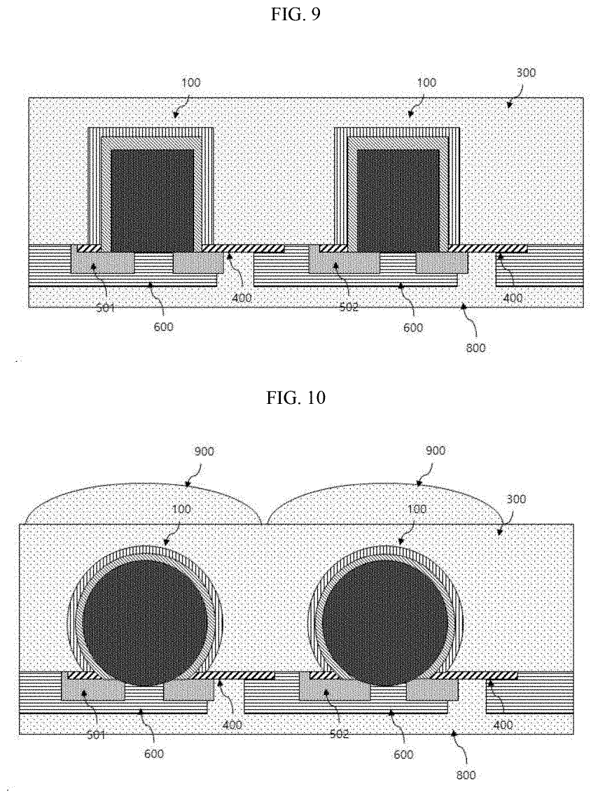

FIG. 9 is a cross-sectional view of a solar cell according to another embodiment of the present invention.

As shown in FIG. 9, the silicon particles can be manufactured not only as a spherical shape but also as a cubic shape. It can also be fabricated in various polyhedral shapes. As long as the solar cell comprises the first electrode 400 and the second electrode 600 contacting with the core portion, the shape of the silicon particle 100 may be variously formed.

An Embodiment Including a Lens on the Top

FIG. 10 is a cross-sectional view of a solar cell according to another embodiment of the present invention. Referring to FIG. 10, a solar cell according to an embodiment of the present invention may further include a lens unit 900 on the optical transparent layer 300 in an area corresponding to the silicon particle 100.

The lens unit 900 functions to concentrate light on the silicon particles 100, thereby enhancing efficiency of power generation.

Further modifications and alternative embodiments of various aspects of the invention may be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed:

1. A method of manufacturing a solar cell, the method comprising the steps of:
(a) positioning a plurality of silicon particles comprising a first layer on the outside on the dummy substrate including a plurality of holes corresponding to the holes;
(b) forming an optically transparent layer on the dummy substrate to include at least one of the silicon particles;
(c) removing the dummy substrate and exposing a portion of the first layer;
(d) forming a plurality of first electrodes, wherein the first electrode is connected to the exposed first layer of each of the silicon particles;
(e) forming an insulating layer on the first electrode;
(f) removing a part of the first layer of silicon particle;
(g) forming a second electrode electrically connected to the portion where the first layer of the silicon particle is removed.

2. The method of claim 1, wherein the silicon particle comprises P-type or N-type silicon, and the first layer comprises a diffusion layer forming a P-N junction on the surface of the light-receiving area of the silicon ball.

3. The method of claim 1, after the step of (a), further comprising the step of:
forming a second layer for anti-reflection on the silicon particles placed on the dummy substrate.

4. The method of claim 1, further comprising the step of:
forming a second layer for anti-reflection to surround the first layer of the silicon particle before the step of (a), and
wherein after removing the dummy substrate, a part of the second layer formed on each of the silicon particles is removed to expose a part of the first layer in the step of (c).

5. The method of claim 1, after the step of (c), further comprising the step of:
forming a reflective layer in a region where the dummy substrate is removed.

6. The method of claim 1,
wherein the first electrode comprises a first layer contact portion electrically connected to the first layer of the silicon particle, a connection terminal portion connected to the second electrode, and an extension part for electrically connecting the first layer contact portion and the connection terminal portion, and
the second electrode comprises a core contact portion electrically connected to the portion where the first layer of the silicon particle is removed, a connection terminal portion connected to the first electrode, and an extension portion electrically connecting the core contact portion and the connection terminal portion.

7. The method of claim 1, after the step of (g), further comprising the step of:
(h) forming a protective layer on the second electrode.

8. The method of claim 7, in the step of (h),
wherein the protective layer comprises an optically transparent layer.

9. The method of claim 1, in the step of (a),
wherein the silicon particles are captured by a template comprising a plurality of inlets and are seated in a plurality of holes on the dummy substrate.

10. The method of claim 1, in the step of (a),
wherein the silicon particles are seated in the plurality of holes using a circulation path continuously providing a plurality of silicon particles along the gravity direction.

11. The method of claim 1,
wherein the silicon particles are formed in a spherical shape.

12. The method of claim 1,
wherein the silicon particles are formed in a polyhedral shape.

13. A method of manufacturing a solar cell, the method comprising the steps of:
(a) positioning a plurality of silicon particles comprising a first layer on the outside on the dummy substrate including a plurality of holes corresponding to the holes;
(b) forming an optically transparent layer on the dummy substrate to include at least one of the silicon particles;
(c) removing the dummy substrate and exposing a portion of the first layer;
(d) forming a plurality of first electrodes, wherein the first electrode is connected to the exposed first layer of each of the silicon particles;
(e) removing a part of the first layer of silicon particle;
(f) forming an insulating layer on the first electrode;
(g) forming a second electrode electrically connected to the portion where the first layer of the silicon particle is removed.

14. A solar cell comprises:
a plurality of silicon particles comprising a first layer on the outside;
an optically transparent layer in which a part of the plurality of silicon particles is embedded;
a plurality of upper electrodes formed under the optically transparent layer and electrically connected to the first layer of the silicon particle;
a plurality of lower electrodes formed below the corresponding upper electrode and electrically connected to the exposed part of the silicon particle 100 through the portion where the first layer is not formed;
an insulating layer placed between the upper electrode and the lower electrode to insulate the upper electrode and the lower electrode,
wherein the upper electrode, the lower electrode, and the insulating layer are formed only on a part of the plane of the optically transparent layer, and
the upper and lower electrodes of the at least one silicon particle are formed independently from the upper electrode and lower electrodes of each of the adjacent silicon particles.

15. The solar cell of claim 14, further comprising:
a protective layer disposed under the lower electrode.

16. The solar cell of claim 14,
wherein the insulating layer comprises a plurality of insulating elements corresponding to each of the upper electrode and the lower electrode.

17. The solar cell of claim 14,
wherein the upper electrode comprises a first layer contact portion electrically connected to the first layer of the silicon particle, a connection terminal portion connected to the lower electrode, and an extension part for electrically connecting the first layer contact portion and the connection terminal portion, and the lower electrode comprises a core contact portion electrically connected to the portion where the first layer of the silicon particle is removed, a connection terminal portion connected to the upper electrode, and an extension portion electrically connecting the core contact portion and the connection terminal portion.

18. The solar cell of claim 17,
wherein the insulating layer comprises a plurality of insulating elements corresponding to each of the upper electrode and the lower electrode, and the insulating elements are formed to be larger than the first layer contact portion of the corresponding upper electrode.

19. The solar cell of claim 17,
wherein the insulating layer comprises a plurality of insulating elements corresponding to each of the upper electrode and the lower electrode, and
the insulating elements are formed to be larger than a core contact portion of the corresponding lower electrode, and electrically isolate the first contact portion of the corresponding upper electrode from the core contact portion and the extended portion of the lower electrode.

20. The solar cell of claim 14, further comprising
a lens unit which is placed on the optically transparent layer and condenses light to the silicon particles.
